(19) United States
(12) Patent Application Publication
(10) Pub. No.: US 2022/0237489 A1
(43) Pub. Date: Jul. 28, 2022

(54) QUANTUM PROCESSOR ARCHITECTURE WITH COMPILER SUPPORT

(71) Applicant: International Business Machines Corporation, Armonk, NY (US)

(72) Inventors: Gushu Li, Goleta, CA (US); Ali Javadiabhari, Sleepy Hollow, NY (US)

(21) Appl. No.: 17/159,730

(22) Filed: Jan. 27, 2021

(51) Int. Cl. G06N 10/00; G06F 17/16; G06F 30/327

(52) U.S. Cl. CPC G06N 10/00; G06F 30/327; G06F 17/16

(57) ABSTRACT

Techniques regarding superconducting quantum processor architectures and/or VQE compiler optimizations are provided. For example, one or more embodiments described herein can regard an apparatus comprising a superconducting quantum processor topology that employs an X-tree architecture to delineate connections between superconducting qubits. Also, a total number of the connections can be less than a total number of the superconducting qubits.

### BACKGROUND

The subject disclosure relates to compiler support for a variational quantum eigensolver (“VQE”) algorithm that can leverage a multilevel hierarchical tree architecture, and more specifically, to a compiler optimization that can map VQE algorithms onto a quantum processor having a multilevel hierarchical tree architecture, such as an X-tree architecture.

### SUMMARY

The following presents a summary to provide a basic understanding of one or more embodiments of the invention. This summary is not intended to identify key or critical elements, or delineate any scope of the particular embodiments or any scope of the claims. Its sole purpose is to present concepts in a simplified form as a prelude to the more detailed description that is presented later. In one or more embodiments described herein, systems, computer-implemented methods, apparatuses and/or computer program products that can leverage domain knowledge and/or program semantics to guide qubit connectivity architecture and/or compiler optimization for one or more VQE algorithms are described.

According to an embodiment, an apparatus is provided. The apparatus can comprise a superconducting quantum processor topology that can employ an X-tree architecture to delineate connections between superconducting qubits. A total number of the connections can be less than a total number of the superconducting qubits.

According to an embodiment, a system is provided. The system can comprise a memory that stores computer executable components. The system can also comprise a processor, operably coupled to the memory, that can execute the computer executable components stored in the memory. The computer executable components can comprise a compiler component that maps a variational quantum eigensolver algorithm to a superconducting quantum processor that can include qubit connectivity characterized by a multilevel hierarchical tree architecture.

According to an embodiment, a computer-implemented method is provided. The computer-implemented method can comprise mapping, by a system operatively coupled to a processor, a variational quantum eigensolver algorithm to a superconducting quantum processor that can include qubit connectivity characterized by a multilevel hierarchical tree architecture.

### BRIEF DESCRIPTION OF THE DRAWINGS

FIGS. 1A-1B illustrates a diagram of an example, non-limiting X-tree architecture for superconducting quantum processors in accordance with one or more embodiments described herein.

FIG. 2 illustrates a diagram of an example, non-limiting graph that can demonstrate the efficacy of one or more X-tree architectures for superconducting quantum processors in accordance with one or more embodiments described herein.

FIG. 3 illustrates a block diagram of an example, non-limiting system that can perform one or more quantum compiler optimizations tailored to VQE algorithms that can minimize mapping overhead on sparse qubit connection quantum processors in accordance with one or more embodiments described herein.

FIG. 4 illustrates a block diagram of an example, non-limiting system that can map physical and/or logical qubits represented by one or more Pauli strings to a multilevel hierarchical tree charactering qubit connectivity in accordance with one or more embodiments described herein.

FIG. 5 illustrates a diagram of example, non-limiting layout and mapping approaches that can be implemented by one or more quantum compilers in accordance with one or more embodiments described herein.

FIG. 6 illustrates a block diagram of an example, non-limiting system that can employ a merge-to-root synthesis and routing approach in which synthesis and routing of a quantum circuit for a VQE algorithm can be performed in conjunction in accordance with one or more embodiments described herein.

FIG. 7 illustrates a diagram of an example, non-limiting merge-to-root synthesis and routing approach that can be employed by one or more quantum compilers in accordance with one or more embodiments described herein.

FIG. 8 illustrates a diagram of an example, non-limiting chart that can demonstrate the efficacy of one or more quantum compilers that can employ a merge-to-root synthesis and routing approach in accordance with one or more embodiments described herein.

FIG. 9 illustrates a computer-implemented method that can facilitate mapping a VQE algorithm onto one or more superconducting quantum processors with sparse qubit connection architectures while reducing mapping overhead in accordance with one or more embodiments described herein.

FIG. 10 illustrates a computer-implemented method that can facilitate mapping a VQE algorithm onto one or more superconducting quantum processor with sparse qubit connection architectures while reducing mapping overhead in accordance with one or more embodiments described herein.

FIG. 11 depicts a cloud computing environment in accordance with one or more embodiments described herein.

FIG. 12 depicts abstraction model layers in accordance with one or more embodiments described herein.

FIG. 13 illustrates a block diagram of an example, non-limiting operating environment in which one or more embodiments described herein can be facilitated.

### DETAILED DESCRIPTION

The following detailed description is merely illustrative and is not intended to limit embodiments and/or application or uses of embodiments. Furthermore, there is no intention to be bound by any expressed or implied information presented in the preceding Background or Summary sections, or in the Detailed Description section.

One or more embodiments are now described with reference to the drawings, wherein like referenced numerals are used to refer to like elements throughout. In the following description, for purposes of explanation, numerous specific details are set forth in order to provide a more thorough understanding of the one or more embodiments. It is evident, however, in various cases, that the one or more embodiments can be practiced without these specific details.

As the number of hardware resources (e.g., qubits and/or qubit connections) employed by a superconducting quantum processor increases, fabrication of the superconducting quantum processor becomes more difficult. For example, with each connected qubit pair, there is a probability that a frequency collision (e.g., a hardware defect) will occur. Also, increased qubit connectivity can result in a higher chance of crosstalk in quantum gates. Therefore, a quantum processor with dense qubit connections generally has a lower yield rate and/or poorer performance.

In contrast, limiting the number of qubit connections can make some two-qubit gates in a quantum program not directly executable because they can only be implemented between two neighboring physical qubits. Traditional quantum compilers employ a qubit mapping and/or routing pass to insert additional operations to resolve these two-qubit dependencies. However, existing quantum compilers are usually at the gate-level and fail to leverage higher-level domain knowledge, resulting in high mapping overhead.

Various embodiments of the present invention can be directed to computer processing systems, computer-implemented methods, apparatus and/or computer program products that facilitate the efficient, effective, and autonomous (e.g., without direct human guidance) synthesis of quantum circuits (e.g., Pauli string simulation quantum circuits) for a VQE algorithm based on qubit connectivity mapping and/or underlying quantum hardware architecture. For example, one or more embodiments described herein can map one or more VQE algorithms onto sparsely-connected superconducting quantum processor architectures with minimal mapping overhead.

The computer processing systems, computer-implemented methods, apparatus and/or computer program products employ hardware and/or software to solve problems that are highly technical in nature (e.g., quantum processor architecture and/or quantum compiler optimization tailored to VQE algorithms), that are not abstract and cannot be performed as a set of mental acts by a human. For example, an individual, or a plurality of individuals, cannot map Pauli string compilations to one or more quantum processor architectures to execute one or more VQE algorithms in accordance with the various embodiments described herein.

Also, one or more embodiments described herein can constitute a technical improvement over conventional quantum compilers by mapping Pauli strings for a VQE algorithm to qubit connectivity characterized by a multilevel hierarchical tree architecture. Additionally, various embodiments described herein can demonstrate a technical improvement over conventional quantum compilers by adaptively synthesizing each quantum circuit according to an evolving logical-to-physical qubit mapping. For example, various embodiments described herein can perform quantum circuit synthesis and routing in conjunction with each other to reduce mapping overhead.

Further, one or more embodiments described herein can have a practical application by considering high-level domain knowledge and/or program semantics to execute one or more VQE algorithms, such as for the analysis of one or more chemistry simulations. For instance, various embodiments described herein can enable execution of complex VQE algorithms, such as quantum chemistry algorithms, on sparsely-connected superconducting quantum processor architectures.

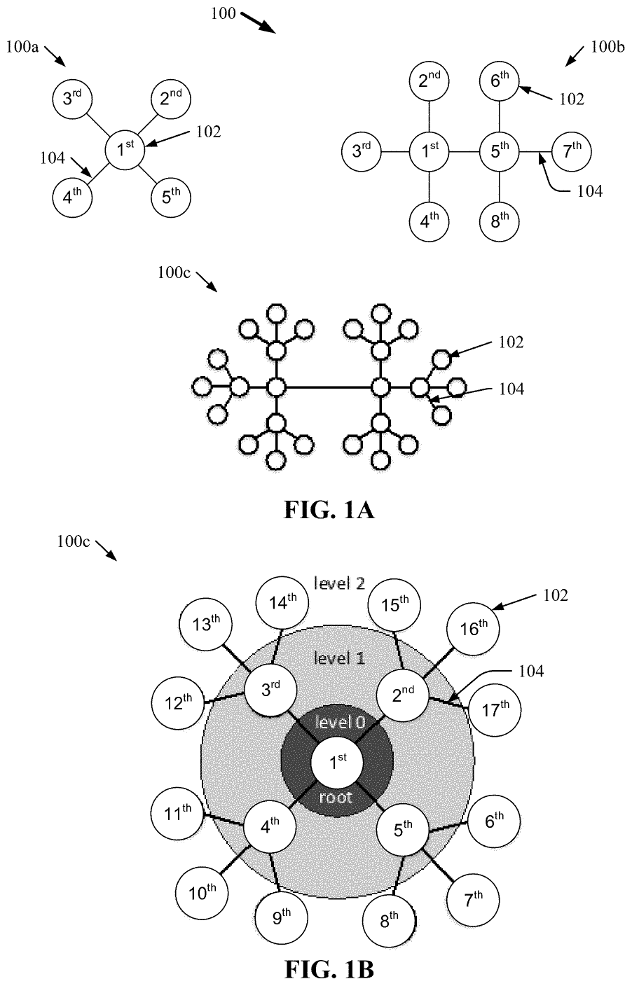

FIGS. 1A-1B illustrates a diagram of example, non-limiting tree structures that can exemplify an X-tree architecture 100 that can characterize qubit connectivity of a superconducting quantum processor. The X-tree architecture 100 can exemplify a type of multilevel hierarchical tree architecture that can be employed to reduce mapping overhead performed by one or more quantum compilers in accordance with one or more embodiments described herein.

VQE algorithms can be executed by one or more quantum computing programs that employ Pauli string simulation circuits. For example, a variational quantum chemistry simulation program can use one or more VQE algorithms to find the ground state energy of a chemical system (e.g., such as a molecule). In a variational quantum chemistry simulation program, the basic building block of a chemistry inspired ansatz can be the Pauli string simulation quantum circuit, which can simulate the time evolution of a Pauli string with a parameter.

Quantum gates, such as two-qubit gates (e.g., controlled NOT (“CNOT”) gates), in each of the Pauli string simulation quantum circuits can form a tree structure to delineate qubit connectivity. The tree structure can be leveraged to guide the design of physical qubit connections within a superconducting quantum processor. Further, the quantum gates (e.g., CNOT gates) in each of the Pauli string simulation quantum circuits can be synthesized into the tree structures without affecting the functionality of the circuit. For example, the same Pauli string can be characterized by a variety of respective qubit connectivity layouts. Various embodiments described herein can leverage the flexibility of Pauli string simulation quantum circuits to design one or more compiler optimizations that can be tailored to the execution of VQE algorithms (e.g., tailored to the execution of one or more variational quantum chemistry simulation programs).

The example X-tree architecture 100 can characterize qubit connectivity of a Pauli string simulation quantum circuit. As shown in FIGS. 1A-1B, the X-tree architecture 100 can represent a superconducting quantum processor topology with sparse qubit connections. As used herein, the term “sparse qubit connections”, and/or grammatical variants thereof, can refer to one or more superconducting quantum processor topologies in which the total number of connections between superconducting qubits is less than the total number of the superconducting qubits. For example, the X-tree architecture 100 can characterize a superconducting quantum processor with sparse qubit connections at least because the X-tree architecture 100 employs one less qubit-to-qubit connection than the total number of qubits. For instance, for “N” qubits, the X-tree architecture 100 employs “N−1” connections to connect all the qubits.

As shown in FIGS. 1A-1B, the X-tree architecture 100 can represent qubit connectivity as a tree structure with no loops. The X-tree architecture 100 can include a plurality of nodes 102 (e.g., represented by circles) coupled together via a plurality of connections 104 (e.g., represented by straight lines). Each node 102 can represent a respective superconducting qubit, and each connection 104 can represent a qubit connection (e.g., via a two-qubit gate, such as a CNOT gate). Amongst the nodes 102, one or more leaf nodes can nodes 102 that branch (e.g., via a connection 104) from a respective root node.

For example, FIG. 1A depicts a first example X-tree architecture 100a comprising five nodes 102 to represent connectivity between five superconducting qubits. For clarity, the nodes 102 are further numbered with a respective numeral (e.g., 1^{st} node 102, 2^{nd} node 102, 3^{rd} node 102, 4^{th} node 102, and/or 5^{th} node 102). In the first example X-tree architecture 100a, the 2^{nd} node 102, 3^{rd} node 102, 4^{th} node 102, and/or 5^{th} node 102 can be leaf nodes with respect to the 1^{st} node 102, which can thereby be a root node. For example, the 2^{nd} node 102, 3^{rd} node 102, 4^{th} node 102, and/or 5^{th} node 102 can branch from the 1^{st} node 102. Thereby, the first example X-tree architecture 100a can delineate a first qubit (e.g., represented by 1^{st} node 102) connected to: a second qubit (e.g., represented by 2^{nd} node 102) via a first quantum gate (e.g., a CNOT gate); a third qubit (e.g., represented by 3^{rd} node 102) via a second quantum gate (e.g., a CNOT gate); a fourth qubit (e.g., represented by 4^{th} node 102) via a third quantum gate (e.g., a CNOT gate); and/or a fifth qubit (e.g., represented by 5^{th} node 102) via a fourth quantum gate (e.g., a CNOT gate). As shown in FIG. 1A, the first example X-tree architecture 100a can characterize qubit connectivity in which five qubits can be coupled via four qubit connections to facilitate a superconducting quantum processor with sparse qubit connections.

Additionally, the size of the X-tree architecture 100 can grow by adding one or more additional nodes 102 to one or more of the leaf nodes. For instance, the second example X-tree example X-tree architecture 100b shown in FIG. 1A comprises eight nodes 102 to represent connectivity between eight superconducting qubits. In particular, a 6^{th} node 102, 7^{th} node 102, and/or 8^{th} node 102 can be further connected to the 5^{th} node 102. As such, the 5^{th} node 102 can be considered a leaf node with respect to the 1^{st} node 102 (e.g., thereby the 1^{st} node 102 can be the root node of the pairing) and a root node with respect to the 6^{th} node 102, 7^{th} node 102, and/or 8^{th} node 102 (e.g., thereby the 6^{th} node 102, 7^{th} node 102, and/or 8^{th} node 102 can respective leaf nodes of the pairings). As shown in FIG. 1A, the second example X-tree architecture 100b can characterize qubit connectivity in which eight qubits can be coupled via seven qubit connections to facilitate a superconducting quantum processor with sparse qubit connections.

Further, by adding additional leaf nodes, the X-tree architecture 100 can continue to grow to characterize superconducting quantum processor topologies comprising even more qubits. For instance, the third example X-tree architecture 100c shown in FIG. 1A can represent twenty-six qubits coupled via twenty-five qubit connections. As exemplified by FIG. 1A, the X-tree architecture 100 is not limited to a particular number of qubits; rather, the X-tree architecture 100 can be scaled to accommodate any desired number of qubits by adding leaf nodes to expand upon the branching of the X-tree architecture 100. In one or more embodiments, each node 102 can be coupled via four or less connections 104 (e.g., a node 102 can serve as a root node for four or less leaf nodes).

As shown in FIG. 1B, the X-tree architecture 100 can be further segmented into multiple levels (e.g., extending from central regions of the X-tree architecture 100 towards perimeter regions of the X-tree architecture 100). For example, a fourth example X-tree architecture 100d is depicted in FIG. 1B. The fourth example X-tree architecture 100d can comprise seventeen nodes 102 (e.g., representing 17 qubits) connected via sixteen connections 104 (e.g., representing 16 qubit connections). Further, the fourth example X-tree architecture 100d can be segmented into three levels: level 0, level 1, and/or level 2. For clarity, the bounds of level 0 is delineated with dark grey shading in FIG. 1B, the bounds of level 1 is delineated with light grey shading in FIG. 1B, and the bounds of level 2 is delineated by the white background in FIG. 1B. The bounds of the respective levels can be such that the connections 104 between root node and leaf node pairings cross between different levels. In various embodiments, physical qubits represented in the X-tree architecture 100 can be positioned at different levels from the root node to the leaf nodes. Additionally, each of the nodes 102 positioned in the outermost level (e.g., the highest level) of the X-tree architecture 100 can be a leaf node.

For example, with regards to the fourth example X-tree architecture 100d, the 2^{nd} node 102, 3^{rd} node 102, 4^{th} node 102, and/or 5^{th} node 102 can be leaf nodes with respect to the 1^{st} node 102 (e.g., a root node). Further, the 1^{st} node 102 can be positioned within level 0; while the 2^{nd} node 102, 3^{rd} node 102, 4^{th} node 102, and/or 5^{th} node 102 can be positioned within level 1. Thereby, the connections 104 between the 2^{nd} node 102, 3^{rd} node 102, 4^{th} node 102, and/or 5^{th} node 102 (e.g., the leaf nodes) and the 1^{st} node 102 (e.g., a root node) can traverse between level 0 and level 1 (e.g., can cross between level 0 and level 1).

Likewise, the 2^{nd} node 102, 3^{rd} node 102, 4^{th} node 102, and/or 5^{th} node 102 can be root nodes with respect to the nodes 102 positioned within level 2. For example, 2^{nd} node 102 can be a root node with respect to the 15^{th} node 102, the 16^{th} node 102, and/or the 17^{th} node 102. As shown in FIG. 1B, the 2^{nd} node 102 can be positioned within level 1; while the 15^{th} node 102, 16^{th} node 102, and/or 17^{th} node 102 can be positioned within level 2. Thereby, the connections 104 between the 15^{th} node 102, 16^{th} node 102, and/or 17^{th} node 102 (e.g., leaf nodes) and the 2^{nd} node 102 (e.g., a root node with respect to the 15^{th} node 102, 16^{th} node 102, and/or 17^{th} node 102) can traverse between level 1 and level 2 (e.g., can cross between level 1 and level 2). As the branching of the X-tree architecture 100 grows, the number of levels in the X-tree architecture 100 can increase. For example, where additional nodes 102 are added to the fourth example X-tree architecture 100d, the additional nodes 102 can be added as leaf nodes and positioned within a level 3 (not shown) in the X-tree architecture 100. Thereby, the X-tree architecture 100 can be embodied as a multileveled hierarchical tree architecture.

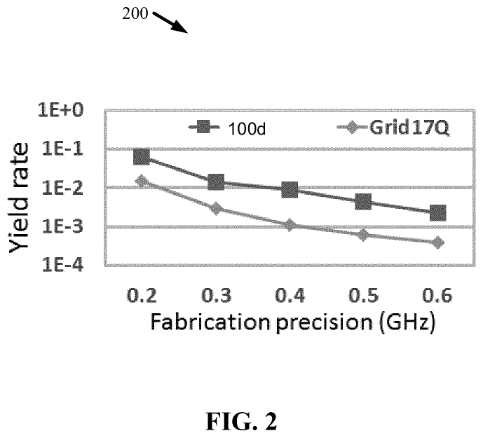

FIG. 2 illustrates a diagram of an example, non-limiting graph 200 that can demonstrate the efficacy of superconducting quantum processor topologies characterized by the X-tree architecture 100 in accordance with one or more embodiments described herein. Repetitive description of like elements employed in other embodiments described herein is omitted for sake of brevity. Graph 200 can compare the fourth example X-tree architecture 100d to a traditional grid architecture “Grid17Q” (e.g., a traditional seventeen node grid, where each node is coupled via at least two connections). Graph 200 demonstrates that a superconducting quantum processor characterized by the X-tree architecture 100 (e.g., a seventeen qubit superconducting quantum processor characterized by fourth example X-tree architecture 100d) can achieve about an eight times higher yield rate compared to a superconducting quantum processor characterized by a traditional two-dimensional grid connection (e.g., a seventeen qubit superconducting quantum processor characterized by a 17 node grid connection). Thereby, the X-tree architecture 100 can enable an efficient superconducting quantum processor architecture with sparse qubit connections and high yield rates.

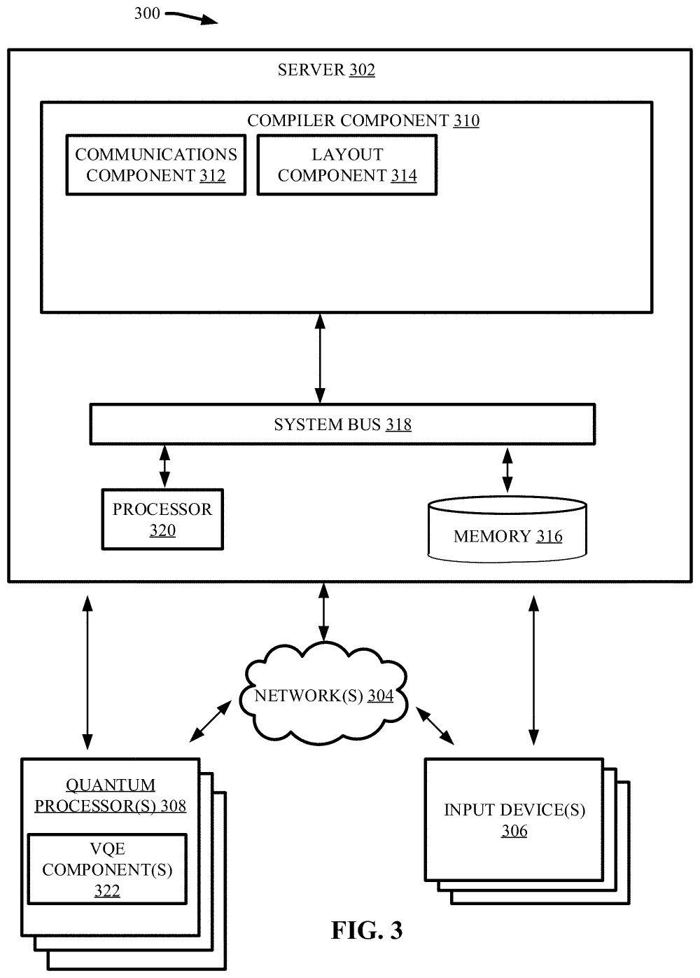

FIG. 3 illustrates a block diagram of an example, non-limiting system 300 that can map one or more VQE algorithms to a multilevel hierarchical architecture of qubit connectivity (e.g., an X-tree architecture 100) to generate one or more quantum circuits for execution of a quantum program (e.g., a variational quantum chemistry simulation). Repetitive description of like elements employed in other embodiments described herein is omitted for sake of brevity. Aspects of systems (e.g., system 300 and the like), apparatuses or processes in various embodiments of the present invention can constitute one or more machine-executable components embodied within one or more machines (e.g., embodied in one or more computer readable mediums (or media) associated with one or more machines). Such components, when executed by the one or more machines (e.g., computers, computing devices, virtual machines, a combination thereof, and/or the like) can cause the machines to perform the operations described.

As shown in FIG. 3, the system 300 can comprise one or more servers 302, networks 304, input devices 306, and/or quantum processors 308. The server 102 can comprise compiler component 310. The compiler component 310 can further comprise communication component 312 and/or layout component 314. Also, the server 302 can comprise or otherwise be associated with at least one memory 316. The server 302 can further comprise a system bus 318 that can couple to various components such as, but not limited to, the compiler component 310 and associated components, memory 316 and/or a processor 320. While a server 302 is illustrated in FIG. 3, in other embodiments, multiple devices of various types can be associated with or comprise the features shown in FIG. 3. Further, the server 302 can communicate with one or more cloud computing environments.

The one or more networks 304 can comprise wired and wireless networks, including, but not limited to, a cellular network, a wide area network (WAN) (e.g., the Internet) or a local area network (LAN). For example, the server 302 can communicate with the one or more input devices 306 and/or quantum processors 308 (and vice versa) using virtually any desired wired or wireless technology including for example, but not limited to: cellular, WAN, wireless fidelity (Wi-Fi), Wi-Max, WLAN, Bluetooth technology, a combination thereof, and/or the like. Further, although in the embodiment shown the compiler component 310 can be provided on the one or more servers 302, it should be appreciated that the architecture of system 300 is not so limited. For example, the compiler component 310, or one or more components of compiler component 310, can be located at another computer device (e.g., such as another server device, a client device, a combination thereof, and/or the like).

The one or more input devices 306 can comprise one or more computerized devices, which can include, but are not limited to: personal computers, desktop computers, laptop computers, cellular telephones (e.g., smart phones), computerized tablets (e.g., comprising a processor), smart watches, keyboards, touch screens, mice, a combination thereof, and/or the like. The one or more input devices 306 can be employed to enter one or more VQE algorithm inputs (e.g., Hamiltonians, quantum programs, quantum circuits, Pauli strings, a combination therefore, and/or the like) into the system 300, thereby sharing (e.g., via a direct connection and/or via the one or more networks 304) said data with the server 302. For example, the one or more input devices 306 can send data to the communications component 312 (e.g., via a direct connection and/or via the one or more networks 304). Additionally, the one or more input devices 306 can comprise one or more displays that can present one or more outputs generated by the system 300 to a user. For example, the one or more displays can include, but are not limited to: cathode tube display (“CRT”), light-emitting diode display (“LED”), electroluminescent display (“ELD”), plasma display panel (“PDP”), liquid crystal display (“LCD”), organic light-emitting diode display (“OLED”), a combination thereof, and/or the like.

In various embodiments, the one or more input devices 306 and/or the one or more networks 304 can be employed to input one or more settings and/or commands into the system 300. For example, in the various embodiments described herein, the one or more input devices 306 can be employed to operate and/or manipulate the server 302 and/or associate components. Additionally, the one or more input devices 306 can be employed to display one or more outputs (e.g., displays, data, visualizations, and/or the like) generated by the server 302 and/or associate components. Further, in one or more embodiments, the one or more input devices 306 can be comprised within, and/or operably coupled to, a cloud computing environment.

For example, in various embodiments the one or more input devices 306 can be employed to enter one or more initial quantum Hamiltonians into the system 300 for analysis via one or more VQE algorithms. For example, the initial quantum Hamiltonian can comprise a sum of Pauli matrices and/or can be obtained by applying one or more versions of a Jordan-Wigner encoding. The initial quantum Hamiltonian can characterize the inter-particle interactions of a chemical system, which can be a set of separable, or inseparable, operators that can evolve the wavefunction to a stationary eigenstate (e.g., wherein the eigenvalues of which are the energy). In one or more embodiments, the system 300 can be initialized with the atomic coordinates (e.g., internal or absolute) of one or more given molecules and/or atom types/basis sets, from which the initial quantum Hamiltonian can be derived.

In various embodiments, the one or more quantum processors 308 can comprise quantum hardware devices that can utilize the laws of quantum mechanics (e.g., such as superposition and/or quantum entanglement) to facilitate computational processing (e.g., while satisfying the DiVincenzo criteria). In one or more embodiments, the one or more quantum processors 308 can comprise a quantum data plane, a control processor plane, a control and measurement plane, and/or a qubit technology.

In one or more embodiments, the quantum data plane can include one or more quantum circuits comprising physical qubits, structures to secure the positioning of the qubits, and/or support circuitry. The support circuitry can, for example, facilitate measurement of the qubits' state and/or perform gate operations on the qubits (e.g., for a gate-based system). In some embodiments, the support circuitry can comprise a wiring network that can enable multiple qubits to interact with each other. Further, the wiring network can facilitate the transmission of control signals via a direct electrical connection and/or electromagnetic radiation (e.g., optical, microwave, and/or low-frequency signals). For instance, the support circuitry can comprise one or more superconducting resonators operatively coupled to the one or more qubits. As described herein the term “superconducting” can characterize a material that exhibits superconducting properties at or below a superconducting critical temperature, such as aluminum (e.g., superconducting critical temperature of 1.2 Kelvin) or niobium (e.g., superconducting critical temperature of 9.3 Kelvin). Additionally, one of ordinary skill in the art will recognize that other superconductor materials (e.g., hydride superconductors, such as lithium/magnesium hydride alloys) can be used in the various embodiments described herein.

In one or more embodiments, the control processor plane can identify and/or trigger a Hamiltonian sequence of quantum gate operations and/or measurements, wherein the sequence executes a program (e.g., provided by a host processor, such as server 302, via compiler component 310) for implementing a quantum algorithm (e.g., a VQE algorithm). For example, the control processor plane can convert compiled code to commands for the control and measurement plane. In one or more embodiments, the control processor plane can further execute one or more quantum error correction algorithms.

In one or more embodiments, the control and measurement plane can convert digital signals generated by the control processor plane, which can delineate quantum operations to be performed, into analog control signals to perform the operations on the one or more qubits in the quantum data plane. Also, the control and measurement plane can convert one or more analog measurement outputs of the qubits in the data plane to classical binary data that can be shared with other components of the system 300.

One of ordinary skill in the art will recognize that a variety of qubit technologies can provide the basis for the one or more qubits of the one or more quantum processors 308. Two exemplary qubit technologies can include trapped ion qubits and/or superconducting qubits. For instance, wherein the quantum processor 308 utilizes trapped ion qubits, the quantum data plane can comprise a plurality of ions serving as qubits and one or more traps that serve to hold the ions in specific locations. Further, the control and measurement plane can include: a laser or microwave source directed at one or more of the ions to affect the ion's quantum state, a laser to cool and/or enable measurement of the ions, and/or one or more photon detectors to measure the state of the ions. In another instance, superconducting qubits (e.g., such as superconducting quantum interference devices “SQUIDs”) can be lithographically defined electronic circuits that can be cooled to milli-Kelvin temperatures to exhibit quantized energy levels (e.g., due to quantized states of electronic charge or magnetic flux). Superconducting qubits can be Josephson junction-based, such as transmon qubits and/or the like. Also, superconducting qubits can be compatible with microwave control electronics, and can be utilized with gate-based technology or integrated cryogenic controls. Additional exemplary qubit technologies can include, but are not limited to: photonic qubits, quantum dot qubits, gate-based neutral atom qubits, semiconductor qubits (e.g., optically gated or electrically gated), topological qubits, a combination thereof, and/or the like.

In one or more embodiments, the communications component 312 can receive one or more initial quantum Hamiltonians from the one or more input devices 306 (e.g., via a direct electrical connection and/or through the one or more networks 304) and share the data with the various associate components of the compiler component 310. Additionally, the communications component 312 can facilitate the sharing of data between the compiler component 310 and the one or more quantum processor 308, and/or vice versa (e.g., via a direct electrical connection and/or through the one or more networks 304).

In various embodiments, the one or more quantum processors 308 can comprise one or more VQE components 322 (e.g., comprised within the control processor plane) that can execute one or more VQE algorithms on the quantum processors 308. In one or more embodiments, the one or more VQE components 322 and the compiler component 310 can function in combination to execute an iterative VQE algorithm based on the one or more initial quantum Hamiltonians. For example, the one or more VQE components 322 and/or compiler component 310 can function in combination to execute one or more variational quantum chemistry simulations.

As used herein the term “variational quantum eigensolver (“VQE”) algorithm”, and grammatical variants thereof, can refer to one or more hybrid quantum-classical computing algorithms that can share computational work between classical computing hardware (e.g., the one or more servers 302 via the compiler component 310) and quantum computing hardware (e.g., the one or more quantum processors 308 via the VQE component 322) to reduce the long coherence times required by all-quantum phase estimation algorithms. A VQE algorithm can be initialized with one or more assumptions regarding the form of a target wavefunction. Based on the one or more assumptions, an ansatz with one or more tunable parameters can be constructed and a quantum circuit capable of producing the ansatz can be designed (e.g., a Pauli string simulation quantum circuit). Throughout execution of the VQE algorithm, the ansatz parameters can be variationally adjusted to minimize the expectation value of resulting Hamiltonian matrix. Classical computing hardware (e.g., the one or more servers 302 via the compiler component 310) can precompute one or more terms of the Hamiltonian matrix and/or update the parameters during optimization of a quantum circuit. The quantum hardware (e.g., the one or more quantum processors 308 via the VQE component 322) can prepare a quantum state (e.g., defined by the current iteration's set of ansatz parameter values) and/or perform measurements of various interaction terms in the Hamiltonian matrix. The state preparation can be repeated over multiple iterations until each individual operator has been measured enough times to derive sufficient statistical data. Additionally, the efficiency of VQE algorithms can be improved by using particle-hole mapping of the quantum Hamiltonian to produce improved starting points for the trail wavefunction. Further, methods to reduce the number of qubits required for electronic structure calculations (e.g., such as qubit tapering) can eliminate redundant degrees of freedom in the Hamiltonian.

In various embodiments, the compiler component 310 can map one or more VQE algorithms to the one or more quantum processors 308, where the one or more quantum processors 308 can have a qubit connectivity characterized by a multilayer hierarchical tree architecture. Further, in various embodiments the one or more quantum processors 308 can have sparse qubit connections. For example, the one or more quantum processors 308 can have a topology characterized by the X-tree architecture 100. For instance, the one or more quantum processors 308 can have sparse qubit connectivity characterized by the X-tree architecture 100, which can be leveraged by the compiler component 310 to minimize mapping overhead while synthesizing and/or routing one or more quantum circuits for execution of a VQE algorithm (e.g., to execute a variational quantum chemistry simulation).

In one or more embodiments, the layout component 314 can generate a hierarchical layout for both physical qubits of the one or more quantum processors 308 and/or logical qubits included in one or more Pauli strings employed by the one or more VQE algorithms. For example, given that the one or more quantum processors 308 have a multilevel hierarchical tree architecture (e.g., an X-tree architecture 100) regarding qubit connectivity, the hierarchical layout generated by the layout component 314 can initially assign program qubits of the one or more VQE algorithms to one or more hardware qubits comprised within the one or more quantum processors 308 and/or characterized by the multilevel hierarchical tree architecture (e.g., an X-tree architecture 100). In various embodiments, the layout component 314 can analyze the one or more Pauli strings employed by the one or more VQE algorithms to execute the quantum program (e.g., the variational quantum chemistry simulation) and initially assign qubits described by the Pauli strings to nodes 102 of the multilevel hierarchical tree architecture. Thereby, the hierarchical layout generated by the layout component 314 can initially map logical qubits (e.g., qubits described by the Pauli strings employed by the VQE algorithm) to physical qubits (e.g., represented by the multilevel hierarchical tree architecture, such as the nodes 102 of the X-tree architecture 100) of the one or more quantum processors 308.

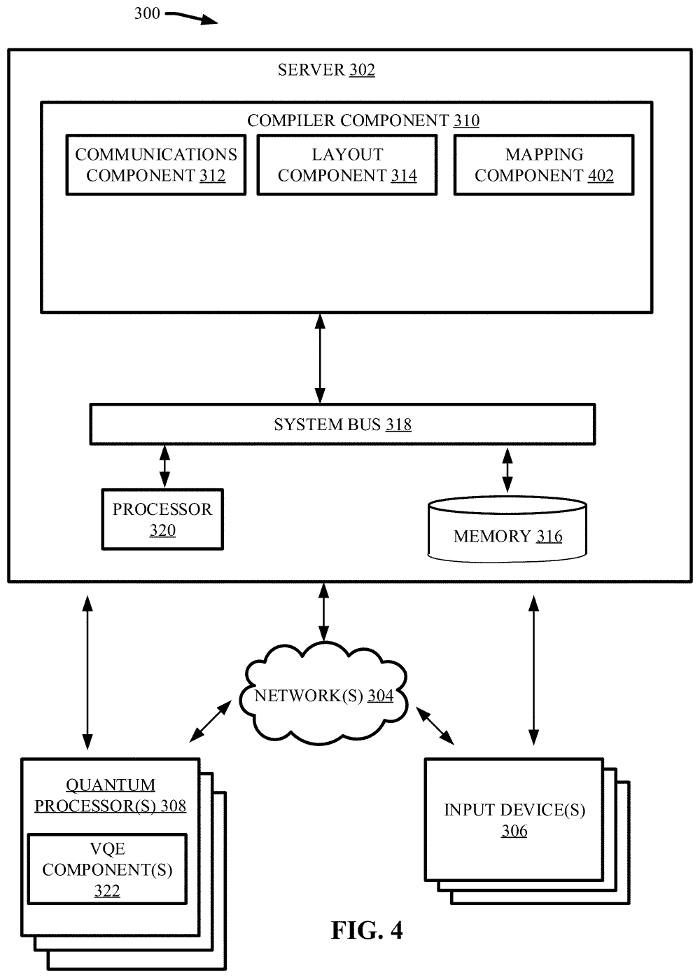

FIG. 4 illustrates a diagram of the example, non-limiting system 300 further comprising mapping component 402 in accordance with one or more embodiments described herein. Repetitive description of like elements employed in other embodiments described herein is omitted for sake of brevity. In various embodiments, the mapping component 402 can further facilitate the layout component 314 in determining a distribution of the logical qubits across a plurality of levels of the multilevel hierarchical tree architecture (e.g., X-tree architecture 100).

For example, the mapping component 402 can analyze the Pauli strings of the one or more VQE algorithms and determine the amount of connectivity associated with the logical qubits during execution of the quantum program. In various embodiments, the amount of connectivity can be characterized by the number of appearances a logical qubit makes in the Pauli strings. For example, each Pauli string can describe a respective quantum computation performed by the VQE algorithm. Thus, the number of quantum computations involving a given logical qubit can be characterized by the number of appearances of the given logical qubit in the Pauli strings. As a logical qubit is involved in more quantum computations, the connectivity of the logical qubit can be considered to increase. For instance, as the number of appearances increases, the amount of connectivity experienced by the associate logical qubit during execution of the quantum program can also increase. For example, a logical qubit with the greatest number of appearances within the Pauli strings can be determined to have the most connectivity within the multilevel hierarchical tree architecture (e.g., X-tree architecture 100).

In various embodiments, the mapping component 402 can assign logical qubits to different levels of the multilevel hierarchical tree architecture (e.g., X-tree architecture 100) based on the associate amount of connectivity. For example, where the level of the tree architecture increases with each iteration of branching (e.g., as exemplified in FIG. 1B with regards to the fourth example X-tree architecture 100d), the logical qubits can be assigned to levels of the tree architecture in order of connectivity; where the logical qubit with the greatest amount of connectivity can be assigned to the lowest level (e.g., nearest the center of the tree architecture), and the logical qubit with the lowest amount of connectivity can be assigned to the highest level (e.g., nearest the perimeter of the tree architecture).

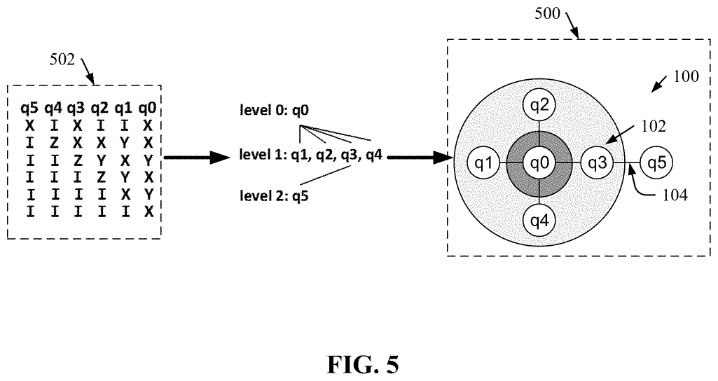

FIG. 5 illustrates a diagram of an example, non-limiting initial hierarchical layout 500 that can be generated by the layout compound 314 and/or mapping component 402 in accordance with one or more embodiments described herein. Repetitive description of like elements employed in other embodiments described herein is omitted for sake of brevity. Quantum computations executable in accordance with the VQE algorithm can be defined via a plurality of Pauli strings.

As shown in FIG. 5, one or more exemplary Pauli strings 502 can include a group of Pauli operators (e.g., “X”, “Y”, “Z”, and “I”) associated with each logical qubit employed by the VQE algorithm to execute the quantum computations. For example, the exemplary Pauli strings 502 depicted in FIG. 5 regard six member groups having Pauli operators associated with six qubits (e.g., where the qubits are represented as “q0”, “q1”, “q2”, “q3”, “q4”, “q5”, and/or “q6”). In the exemplary Pauli strings 502, qubit q0 has the greatest number of appearances (e.g., the greatest number of “X”, “Y”, and/or “Z” Pauli operator associations within the set of exemplary Pauli strings 502). In contrast, qubit q5 has the least number of appearances (e.g., the least number of “X”, “Y”, and/or “Z” Pauli operator associations within the set of exemplary Pauli strings 502).

As shown in FIG. 5, the compiler component 310 (e.g., via layout component 314 and/or mapping component 402) can assign the logical qubits to different levels of the tree architecture (e.g., X-tree architecture 100) based on the qubits' connectivity (e.g., as determined based on the number of appearances within the Pauli strings). In various embodiments, the mapping component 402 can determine how many quantum computations employ each of the logical qubits of the VQE algorithm, and thereby the amount of connectivity associated with each logical qubit, based on the number of appearances (e.g., number of “X”, “Y”, and/or “Z” Pauli operator associations within the set Pauli strings) of the respective logical qubits in the Pauli strings.

For example, the qubit associated with the greatest number of appearances in the exemplary Pauli strings 502 (e.g., qubit q0) can be assigned to the lowest level (e.g., level 0) of the tree architecture (e.g., X-tree architecture 100) by the mapping component 402. Also, the qubit associated with the least number of appearances in the exemplary Pauli strings 502 (e.g., qubit q5) can be assigned to the highest level (e.g., level 2) of the tree architecture (e.g., X-tree architecture 100) by the mapping component 402. Further, the qubits associated with neither the greatest nor least number of appearances in the exemplary Pauli strings 502 (e.g., qubit q1, qubit q2, qubit q3, and/or qubit q4) can be assigned to one or more intermediate levels (e.g., level 1) of the tree architecture (e.g., X-tree architecture 100) by the mapping component 402.

Additionally, the compiler component 310 (e.g., via layout compound 314 and/or mapping component 402) can map the qubits to the nodes 102 of the tree architecture (e.g., X-tree architecture 100) based on the level assignments. For clarity, the boundary of level 0 within the tree architecture of the exemplary hierarchical layout 500 is delineated by dark grey shading in FIG. 5, the boundary of level 1 within the tree architecture of the exemplary hierarchical layout 500 is delineated by light grey shading in FIG. 5, and the boundary of level 2 within the tree architecture of the exemplary hierarchical layout 500 is delineated by the white background in FIG. 5. In various embodiments, as the positioning of the mapped qubits approaches the center of the multilevel hierarchical tree architecture (e.g., X-tree architecture 100), the number of qubit connections experienced by the mapped qubits throughout execution of the VQE algorithm increases. For example, in the exemplary set of Pauli strings 502, qubit q0 is shown to be involved in the most quantum computations throughout execution of the VQE algorithm (e.g., as evidence by the number of appearance within the Pauli strings) and therefore can be positioned within the center-most level (e.g., level 0) of the multilevel hierarchical tree architecture (e.g., X-tree architecture 100). In contrast, in the exemplary set of Pauli strings 502, qubit q5 is shown to be involved in the fewest quantum computations throughout execution of the VQE algorithm (e.g., as evidence by the number of appearance within the Pauli strings) and therefore can be positioned within the level further from center (e.g., level 2) of the multilevel hierarchical tree architecture (e.g., X-tree architecture 100).

As a result of mapping qubits based on level assignments within the tree architecture (e.g., X-tree architecture 100), qubits mapped to nodes 102 nearest the center of the multilevel hierarchical tree architecture can be qubits that can experience the greatest amount of qubit connection variety during execution of the VQE algorithm. In contrast, qubits mapped to nodes 102 furthest from the center of the multilevel hierarchical tree architecture can be qubits that can be expected to experience the least amount of qubit connection variety during the execution of the VQE algorithm.

With each synthesis of a quantum circuit employed by the VQE algorithm, the logical qubits can be routed to new physical qubit mappings that facilitate different qubit connectivity schemes delineated by the respective quantum circuit. As the number of routing operations employed to establish the desired connectivity increases, so to does the mapping overhead. However, the initial hierarchical layout described herein can enable a reduction in the number of routing operations by mapping highly trafficked qubits (e.g., qubits involved in numerous quantum computations) to one or more central levels of the tree architecture (e.g., X-tree architecture 100), and thereby in closer proximity to each other. In other words, qubits initially mapped to central levels (e.g., level 0 in the fourth exemplary X-architecture 100d) in the tree architecture can be routed to desired qubit connections (e.g., desired root node to leaf node pairings) via fewer operations than qubits initially mapped to perimeter levels (e.g., level 2 in the fourth exemplary X-architecture 100d) in the tree architecture.

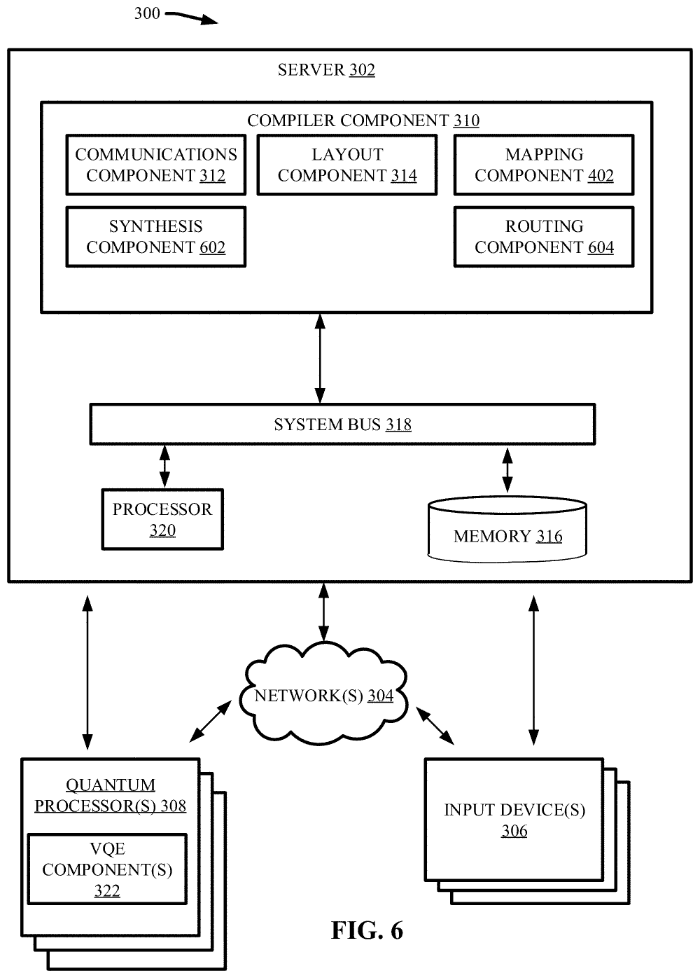

FIG. 6 illustrates a diagram of the example, non-limiting system 300 further comprising synthesis component 602 and/or routing component 604 in accordance with one or more embodiments described herein. Repetitive description of like elements employed in other embodiments described herein is omitted for sake of brevity. In various embodiments, the compiler component 310 (e.g., via synthesis component 602 and/or routing component 604) can employ a merge-to-root synthesis and routing approach to generate one or more quantum circuits (e.g., Pauli string simulation quantum circuits) for execution of the one or more VQE algorithms (e.g., execution of a variational quantum chemistry simulation).

For example, with each iteration of the VQE algorithm the compiler component 310 (e.g., via synthesis component 602 and/or routing component 604) can synthesize a respective quantum circuit (e.g., Pauli string simulation quantum circuit) to express a respective Pauli string, and can route the current logical-to-physical qubit mapping being employed to enable the qubit connectivity of the synthesized quantum circuit. In one or more embodiments, the synthesis component 602 can synthesize a quantum circuit that expresses a Pauli string from the plurality of Pauli strings through a series of qubit connection selections. Further, the synthesis component 602 can select each qubit connection (e.g., between the logical qubits) based on an effect a previously selected qubit connection had on the mapping of the physical qubits with the logical qubits. Additionally, the routing component 604 can alter the position of a logical qubit on the multilevel hierarchical tree architecture based on the qubit connection selections performed by the synthesis component 602. For example, the routing component 604 can execute one or more routing operations that define a relocation of one or more logical qubits from one node 102 of the tree architecture to another node 102, thereby moving the logical qubits to one or more nodes 102 (e.g., and thereby physical qubit assignments) capable of establishing the selected qubit connection. In various embodiments, synthesizing the quantum circuit and executing the routing operation can be performed in conjunction. For example, routing operations employed by the routing component 604 can alter the logical-to-physical qubit mapping, whereupon the next synthesis operation (e.g., defining a qubit connection) employed by the synthesis component 602 can be selected based on the altered state of the qubit mapping.

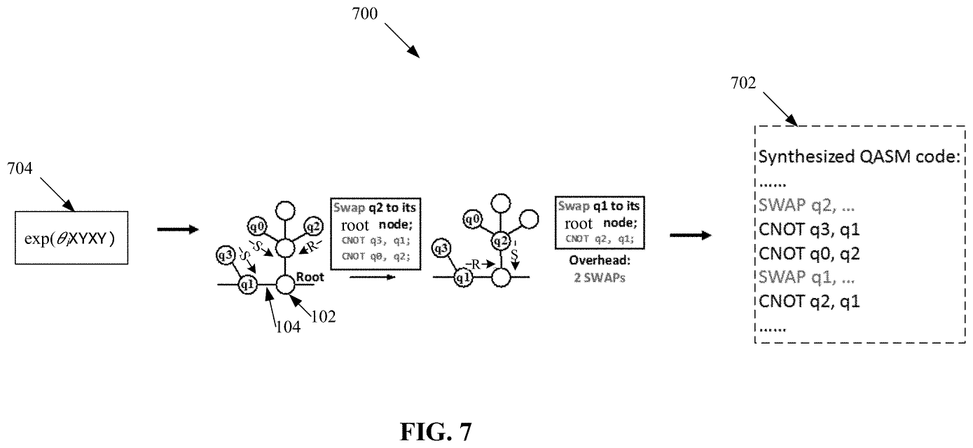

FIG. 7 illustrates a diagram of an example, non-limiting merge-to-root synthesis and routing approach 700 that can be implemented by the synthesis component 602 and/or routing component 604 in accordance with one or more embodiments described herein. Repetitive description of like elements employed in other embodiments described herein is omitted for sake of brevity. The exemplary merge-to-root synthesis and routing approach 700 depicted in FIG. 7 can exemplify the features of the synthesis component 602 and/or routing component 604 with regards to an exemplary quantum circuit. In various embodiments, a merge-to-root synthesis and routing approach performed by the compiler component 310 (e.g., such as exemplary merge-to-root synthesis and routing approach 700) can be implemented with a quantum processor 308 having qubit connectivity characterized by a multilevel hierarchical tree architecture (e.g., X-tree architecture 100). For example, the layout component 314 and/or mapping component 402 can generate an initial hierarchical layout of the logical-to-physical qubit mapping that initially maps logical qubits that are likely to experience multiple different qubit connections during execution of the VQE algorithm in central levels of the tree architecture (e.g., central levels such as exemplary level 0 and/or 1 in the fourth exemplary X-tree architecture 100d); thereby facilitating the merge-to-root synthesis and routing approach 700 by enabling various quantum circuit synthesis options to be achievable with minimal routing operations.

As described herein, the same Pauli string can be expressed by multiple different Pauli string simulation quantum circuits, each describing a variant scheme of qubit connectivity that can be employed to achieve the quantum computation of the Pauli string. Thus, for a given Pauli string, a plurality of quantum circuits can be available for synthesis. At least due to the positioning of high traffic logical qubits (e.g., qubits likely to experience a great amount of qubit connectivity throughout the VQE algorithm) within central levels of the tree architecture (e.g., X-tree architecture 100), multiple qubit connection options can be available for selection by the synthesis component 602 to synthesize a quantum circuit. Thereby, the synthesis component 602 can select qubit connections in conjunction with routing operations employed by the routing component 604 to adaptively synthesize a quantum circuit that expresses the given Pauli string with minimal mapping overhead.

The exemplary merge-to-root synthesis and routing approach 700 shown in FIG. 7, depicts the synthesis of an exemplary Pauli string simulation quantum circuit 702 (e.g., described in quantum assembly (“QASM”) code) from an exemplary input Pauli string 704. For instance, the exemplary input Pauli string 704 can regard a quantum computation involving four logical qubits (e.g., represented in FIG. 7 by qubit q1, qubit q2, qubit q3, and qubit q4). As shown in FIG. 7, the logical qubits can be already mapped to the multilevel hierarchical tree architecture (e.g., X-tree architecture 100) of the given quantum processor 308. For instance, the currently mapped position of the logical qubits can be residual positions from a previous iteration of the VQE algorithm. In another instance, the currently mapped position of the logical qubits can be positions established by the initial hierarchical layout in accordance with one or more embodiments described herein. The synthesis component 602 and/or routing component 604 can operate in conjunction with each other to re-map the logical qubits to nodes 102 enabling qubit connections described by a synthesized quantum circuit (e.g., exemplary Pauli string simulation quantum circuit 702) that expresses the given Pauli string (e.g., exemplary input Pauli string 704).

As shown in FIG. 7, synthesis operations employed by the synthesis component 602 are depicted with “S” arrows, and routing operations employed by the routing component 604 are depicted with “R” arrows. For clarity, the synthesis and routing operations are depicted with regards to an illustration of at least a portion of the multilevel hierarchical tree architecture (e.g., X-tree architecture 100). Additionally, the synthesis and routing operations are depicted as QASM code that, when compiled, can describe the synthesized quantum circuit (e.g., exemplary Pauli string simulation quantum circuit 702). In various embodiments, the synthesis component 602 can employ the one or more synthesis operations to define a selected qubit connection. For example, the one or more synthesis operations can define one or more quantum logic gates between qubits, such as two-qubit gates (e.g., CNOT gates, and/or the like). In various embodiments, the routing component 604 can employ the one or more routing operations to route logical qubits to alternate nodes 102 in the tree architecture. For instance, the routing operations can route a given logical qubit from an initial node 102 to another node 102 capable of establishing a qubit connection defined by one or more synthesis operations. For example, the one or more routing operations can define one or more quantum logic gates that adjust qubit basis states, such as swap (“SWAP”) gates, and/or the like.

For example, in the exemplary merge-to-root synthesis and routing approach 700 shown in FIG. 7, the input Pauli string 704 that can be expressed via a plurality of different qubit connection combinations. The synthesis component 602 can select a first qubit connection from a first pool of qubit connections that are included in quantum circuit variants capable of expressing the given Pauli string (e.g., input Pauli string 704). Further, the synthesis component 602 can select the first qubit connection based on the number of routing operations that would need to be employed to enable the first qubit connection on the existing logical-to-physical qubit mapping. For instance, with regards to the initial logical-to-physical qubit mapping shown in FIG. 7, where the first pool of qubit connections includes a qubit connection between qubits q2 and q3 and a qubit connection between qubits q3 and q1; the synthesis component 602 can select the qubit q3 and q1 connection at least because qubits q3 and q1 are already mapped to connected nodes 102 and thus a synthesis operation (e.g., a CNOT gate) employed by the synthesis component 602 to define the qubit connection does not need an associate routing operation to be enabled (e.g., as shown in FIG. 7).

Additionally, the synthesis component 602 can select a second qubit connection from a second pool of qubit connections that are included in quantum circuit variants having the first qubit connection and are capable of expressing the given Pauli string (e.g., input Pauli string 704). Further, the synthesis component 602 can select the second qubit connection based on the number of routing operations that would need to be employed to enable the second qubit connection on the state of the logical-to-physical qubit mapping post establishment of the first qubit connection. Where the first qubit connection can be established without one or more routing operations (e.g., as depicted in FIG. 7) the state of the logical-to-physical qubit mapping can remain unchanged. For instance, where the second pool of qubit connections includes a qubit connection between qubits q0 and q1 and a qubit connection between qubits q0 and q2; the synthesis component 602 can employ a synthesis operation (e.g., a CNOT gate) that defines the qubit q0 and q2 connection at least because the qubit q0 and q2 connection can be established with fewer routing operations than the qubit q0 and q1 connection. For example, qubit q2 can be routed to a node 102 that is connected to the node of qubit q0 via a single routing operation, while qubit q1 requires at least two routing operations to be routed to a node 102 connected to the node of qubit q0. As shown in FIG. 7, the routing component 604 can employ a single routing operation (e.g., a SWAP gate) to alter the position of the qubit q2 to a root node in the tree architecture that is connected to the node 102 of qubit q0.

Further, the synthesis component 602 can select a third qubit connection from a third pool of qubit connections that are included in quantum circuit variants having the first and second qubit connections and are capable of expressing the given Pauli string (e.g., input Pauli string 704). Further, the synthesis component 602 can select the third qubit connection based on the number of routing operations that would need to be employed to enable the third qubit connection on the state of the logical-to-physical qubit mapping post establishment of the second qubit connection. In the depicted example, the state of the logical-to-physical mapping was altered by the last routing operation (e.g., SWAP gate of qubit q2) employed by the routing component 604. For instance, where the third pool of qubit connections includes a qubit connection between qubits q2 and q3 and a qubit connection between qubits q2 and q1; the synthesis component 602 can select a synthesis operation (e.g., a CNOT gate) that defines the qubit q2 and q1 connection at least because the qubit q2 and q1 connection can be established with fewer routing operations than the qubit q2 and q3 connection. For example, qubit q1 or q2 can be routed to a node 102 connected to the node 102 of the other respective qubit via a single routing operation, while numerous routing operations would be necessitated to achieve a connection between qubits q2 and q3 without impeding the first and second qubit connections described above. As shown in FIG. 7, the routing component 604 can employ a single routing operation (e.g., a SWAP gate) to route the qubit q1 to a root node in the tree architecture that is connected to the node 102 of qubit q2.

One of ordinary skill in the art will recognize that the exemplary merge-to-root synthesis and routing approach 700 is described herein to exemplify various features of the compiler component 310 (e.g., via synthesis component 602 and/or routing component 604), and the architecture of the merge-to-root synthesis and routing approach practiced by the compiler component 310 is not so limited. For example, embodiments comprising more than three qubit connection selections and/or more than four logical qubits are also envisaged. For instance, the various features described herein can be scaled to meet the one or more demands of the VQE algorithm.

By adaptively selecting synthesis operations based on the initial mapping state and/or how the mapping state evolves throughout the circuit synthesis, the synthesis component 602 can synthesize a quantum circuit that expresses the given Pauli string with minimal routing operations (e.g. minimal mapping overhead). Further, the mapping of high traffic logical qubits to central levels in the multilevel hierarchical tree architecture in the initial hierarchical layout, in accordance with various embodiments describe herein, can increase the number of qubit connection candidates that can be selected with minimal routing operations. Moreover, in various embodiments, multilevel hierarchical tree architectures, such as the X-tree architecture 100, can enable the generation of the initial hierarchical layout with regards to quantum processors 308 that have sparse qubit connections and thus high yield rates.

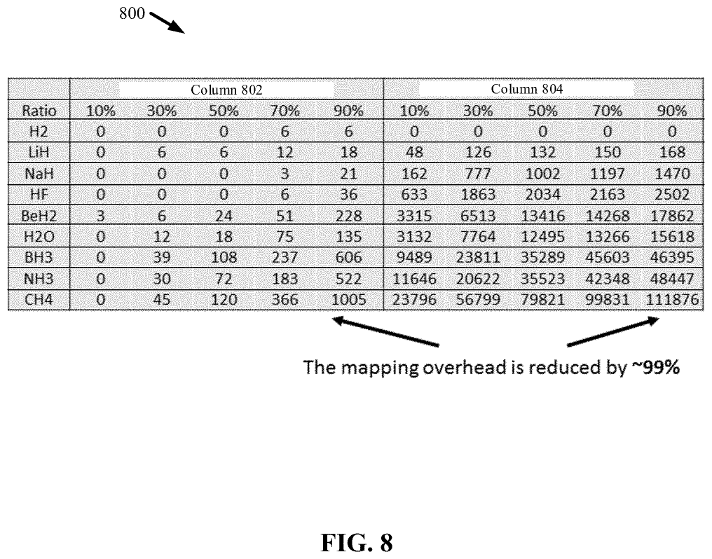

FIG. 8 illustrates a diagram of an example, non-limiting table 800 that can demonstrate the efficacy of the merge-to-root synthesis and routing approach employed on the X-tree architecture 100 by the compiler component 310 in accordance with one or more embodiments described herein. Repetitive description of like elements employed in other embodiments described herein is omitted for sake of brevity. Table 800 can demonstrate the efficacy of the various features of the compiler component 310 described herein with regards to mapping overhead (e.g., number of routing operations). Column 802 depicts the mapping overhead resulting from running a variational quantum chemistry simulation for the depicted molecules (e.g., hydrogen gas (“H₂”), lithium hydride (“LiH”), sodium hydride (“NaH”), hydrogen fluoride (“HF”), beryllium hydride (“BeH₂”), water (“H₂O”), borane (“BH₃”), ammonia (“NH₃”), and methane (“CH₄”)) with the compiler component 310 described herein on the fourth example X-tree architecture 100d. Column 804 depicts the mapping overhead resulting from running the same variational quantum chemistry simulation for the depicted molecules with a traditional VQE compiler (e.g., a sabre compiler) on the fourth example X-tree architecture 100d. As shown in FIG. 8, the compiler component 310 can execute the VQE algorithm while reducing mapping overhead by nearly 99%, as compared to the traditional compiler.

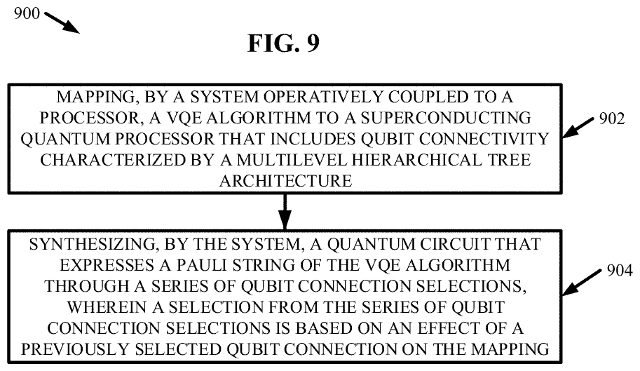

FIG. 9 illustrates a flow diagram of an example, non-limiting computer-implemented method 900 that can map one or more VQE algorithms onto sparse qubit connection quantum processors 308 with reduced mapping overhead in accordance with one or more embodiments described herein. Repetitive description of like elements employed in other embodiments described herein is omitted for sake of brevity.

At 902, the computer-implemented method 900 can comprise mapping (e.g., via layout component 314 and/or mapping component 402), by a system 300 operatively coupled to a processor 320, one or more VQE algorithms to one or more superconducting quantum processors 308 that can include qubit connectivity characterized by a multilevel hierarchical tree architecture (e.g., an X-tree architecture 100). In various embodiments, the mapping at 902 can comprise generating a hierarchical layout (e.g., exemplary hierarchical layout 500) based on the amount of connectivity expected for each of the logical qubits. For instance, logical qubits with high connectivity throughout the VQE algorithm (e.g., as evidenced by a plethora of appearances in the Pauli strings) can be mapped to physical qubits positioned in central levels of the tree architecture (e.g., high traffic qubits can be mapped to root nodes).

At 904, the computer-implemented method 900 can comprise synthesizing (e.g., via synthesis component 602 and/or routing component 604), by the system 300, a quantum circuit (e.g., a Pauli string simulation quantum circuit) that can express a Pauli string of the VQE algorithm through a series of qubit connection selections, where each qubit connection selection can be based on an effect on the logical-to-physical qubit mapping that resulted from a previous qubit connection selection. For example, a first selected qubit connection can be enabled by one or more routing operations. As a result of the accompanied routing, establishing the first selected qubit connection can alter the current logical-to-physical qubit mapping (e.g., can alter mapping initially established at 902 and/or established during a previous iteration of the VQE algorithm). A second qubit connection in the series of selections that compile to synthesize the quantum circuit can be selected based on the altered mapping; thereby accounting for how the previous routing operations can influence routing operations associated with each possible qubit connection candidate. By adaptively selecting qubit connections based on the evolving state of the logical-to-physical qubit mapping, the computer-implemented method 900 can synthesize a quantum circuit that expresses the given Pauli string while also minimizing mapping overhead (e.g., as demonstrated by the exemplary merge-to-root synthesis and routing approach 700 depicted in FIG. 7).

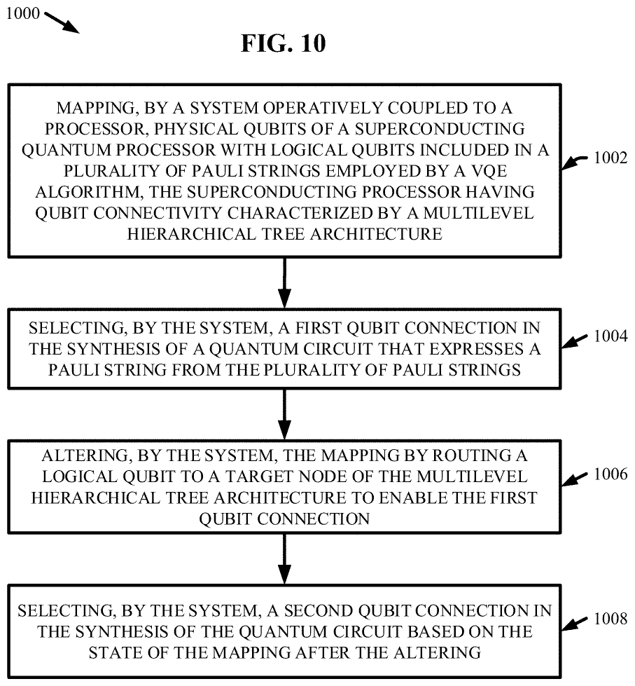

FIG. 10 illustrates a flow diagram of an example, non-limiting computer-implemented method 1000 that can map one or more VQE algorithms onto sparse qubit connection quantum processors 308 with reduced mapping overhead in accordance with one or more embodiments described herein. Repetitive description of like elements employed in other embodiments described herein is omitted for sake of brevity.

At 1002, the computer-implemented method 1000 can comprise mapping (e.g., via layout component 314 and/or mapping component 402), by a system 300 operatively coupled to a processor 320, physical qubits of a superconducting quantum processor 308 with logical qubits included in a plurality of Pauli strings employed by a VQE algorithm. In various embodiments, the superconducting quantum processor 308 can have a qubit connectivity characterized by a multilevel hierarchical tree architecture, such as the X-tree architecture 100 described herein. In various embodiments, the mapping at 902 can comprise generating a hierarchical layout (e.g., exemplary hierarchical layout 500) based on the amount of connectivity expected for each of the logical qubits. For instance, logical qubits with high connectivity throughout the VQE algorithm (e.g., as evidenced by a plethora of appearances in the Pauli strings) can be mapped to physical qubits positioned in central levels of the tree architecture (e.g., high traffic qubits can be mapped to root nodes).

Further, the computer-implemented method 1000 can synthesize a quantum circuit (e.g., a Pauli string simulation quantum circuit) for each of the Pauli strings, and the quantum circuits can be executable by the superconducting quantum processor 308 by routing qubits through the logical-to-physical qubit mapping. Various quantum circuits, each with a respective qubit connectivity, can express the same Pauli string. However, the quantum circuit variants can be associated with respective amounts of routing operations to enable execution on the superconducting quantum processor 308. Selecting a quantum circuit variant that requires the least amount of routing to effectuate can reduce mapping overhead associated with execution of the VQE algorithm. In accordance with various embodiments described herein, the computer-implemented method 1000 can synthesize the quantum circuit while minimizing mapping overhead by synthesizing the quantum circuit through a series of qubit connection selections, where each qubit connection is adaptively chosen based on how the logical-to-physical qubit mapping evolves in response to the previous selections (e.g., as demonstrated in the exemplary merge-to-root synthesis and routing approach 700 depicted in FIG. 7).

For example, at 1004 the computer-implemented method 1000 can comprise selecting (e.g., via synthesis component 602), by the system 300, a first qubit connection in the synthesis of the quantum circuit. The first qubit connection can be a qubit connection that requires the minimum amount of routing operations to effectuate, as compared to the other qubit connection candidates in a pool of qubit connections that are included in one or more of the quantum circuit variants that can express the Pauli string. In one or more embodiments, the computer-implemented method 1000 can comprise altering (e.g., via routing component 604), by the system 300, the logical-to-physical qubit mapping by routing a logical qubit to a target node of the multilevel hierarchical tree architecture to enable the first qubit connection. At 1008, the computer-implemented method 1000 can then comprise selecting (e.g., via synthesis component 602), by the system 300, a second qubit connection in the synthesis of the quantum circuit. The second qubit connection can be a qubit connection that requires the minimum amount of routing operations to effectuate on the altered logical-to-physical qubit mapping, as compared to the other qubit connection candidates in a pool of qubit connections that are included in one or more of the quantum circuit variants that further include the first qubit connection and can express the Pauli string. Further, the computer-implemented method 1000 can repeat steps 1004 to 1008 until synthesis of a quantum circuit that expresses the given Pauli string is achieved.

It is to be understood that although this disclosure includes a detailed description on cloud computing, implementation of the teachings recited herein are not limited to a cloud computing environment. Rather, embodiments of the present invention are capable of being implemented in conjunction with any other type of computing environment now known or later developed.

Cloud computing is a model of service delivery for enabling convenient, on-demand network access to a shared pool of configurable computing resources (e.g., networks, network bandwidth, servers, processing, memory, storage, applications, virtual machines, and services) that can be rapidly provisioned and released with minimal management effort or interaction with a provider of the service. This cloud model may include at least five characteristics, at least three service models, and at least four deployment models.

Characteristics are as follows:

On-demand self-service: a cloud consumer can unilaterally provision computing capabilities, such as server time and network storage, as needed automatically without requiring human interaction with the service's provider.

Broad network access: capabilities are available over a network and accessed through standard mechanisms that promote use by heterogeneous thin or thick client platforms (e.g., mobile phones, laptops, and PDAs).

Resource pooling: the provider's computing resources are pooled to serve multiple consumers using a multi-tenant model, with different physical and virtual resources dynamically assigned and reassigned according to demand. There is a sense of location independence in that the consumer generally has no control or knowledge over the exact location of the provided resources but may be able to specify location at a higher level of abstraction (e.g., country, state, or datacenter).

Rapid elasticity: capabilities can be rapidly and elastically provisioned, in some cases automatically, to quickly scale out and rapidly released to quickly scale in. To the consumer, the capabilities available for provisioning often appear to be unlimited and can be purchased in any quantity at any time.

Measured service: cloud systems automatically control and optimize resource use by leveraging a metering capability at some level of abstraction appropriate to the type of service (e.g., storage, processing, bandwidth, and active user accounts). Resource usage can be monitored, controlled, and reported, providing transparency for both the provider and consumer of the utilized service.

Service Models are as follows:

Software as a Service (SaaS): the capability provided to the consumer is to use the provider's applications running on a cloud infrastructure. The applications are accessible from various client devices through a thin client interface such as a web browser (e.g., web-based e-mail). The consumer does not manage or control the underlying cloud infrastructure including network, servers, operating systems, storage, or even individual application capabilities, with the possible exception of limited user-specific application configuration settings.

Platform as a Service (PaaS): the capability provided to the consumer is to deploy onto the cloud infrastructure consumer-created or acquired applications created using programming languages and tools supported by the provider. The consumer does not manage or control the underlying cloud infrastructure including networks, servers, operating systems, or storage, but has control over the deployed applications and possibly application hosting environment configurations.

Infrastructure as a Service (IaaS): the capability provided to the consumer is to provision processing, storage, networks, and other fundamental computing resources where the consumer is able to deploy and run arbitrary software, which can include operating systems and applications. The consumer does not manage or control the underlying cloud infrastructure but has control over operating systems, storage, deployed applications, and possibly limited control of select networking components (e.g., host firewalls).

Deployment Models are as follows:

Private cloud: the cloud infrastructure is operated solely for an organization. It may be managed by the organization or a third party and may exist on-premises or off-premises.

Community cloud: the cloud infrastructure is shared by several organizations and supports a specific community that has shared concerns (e.g., mission, security requirements, policy, and compliance considerations). It may be managed by the organizations or a third party and may exist on-premises or off-premises.

Public cloud: the cloud infrastructure is made available to the general public or a large industry group and is owned by an organization selling cloud services.

Hybrid cloud: the cloud infrastructure is a composition of two or more clouds (private, community, or public) that remain unique entities but are bound together by standardized or proprietary technology that enables data and application portability (e.g., cloud bursting for load-balancing between clouds).

A cloud computing environment is service oriented with a focus on statelessness, low coupling, modularity, and semantic interoperability. At the heart of cloud computing is an infrastructure that includes a network of interconnected nodes.

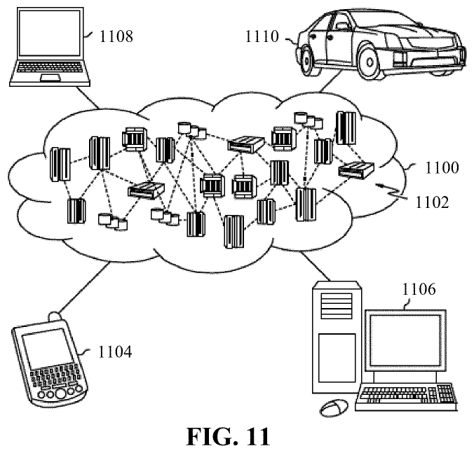

Referring now to FIG. 11, illustrative cloud computing environment 1100 is depicted. As shown, cloud computing environment 1100 includes one or more cloud computing nodes 1102 with which local computing devices used by cloud consumers, such as, for example, personal digital assistant (PDA) or cellular telephone 1104, desktop computer 1106, laptop computer 1108, and/or automobile computer system 1110 may communicate. Nodes 1102 may communicate with one another. They may be grouped (not shown) physically or virtually, in one or more networks, such as Private, Community, Public, or Hybrid clouds as described hereinabove, or a combination thereof. This allows cloud computing environment 1100 to offer infrastructure, platforms and/or software as services for which a cloud consumer does not need to maintain resources on a local computing device. It is understood that the types of computing devices 1104-1110 shown in FIG. 11 are intended to be illustrative only and that computing nodes 1102 and cloud computing environment 1100 can communicate with any type of computerized device over any type of network and/or network addressable connection (e.g., using a web browser).

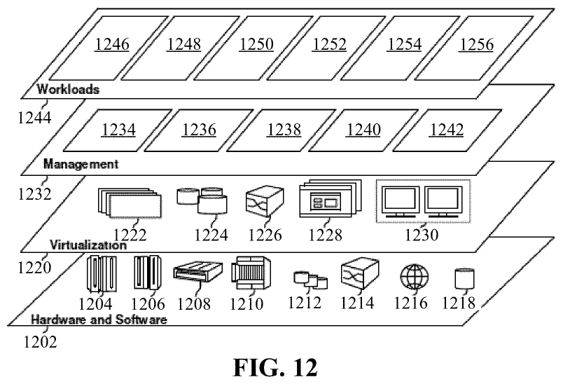

Referring now to FIG. 12, a set of functional abstraction layers provided by cloud computing environment 1100 (FIG. 11) is shown. Repetitive description of like elements employed in other embodiments described herein is omitted for sake of brevity. It should be understood in advance that the components, layers, and functions shown in FIG. 12 are intended to be illustrative only and embodiments of the invention are not limited thereto. As depicted, the following layers and corresponding functions are provided.

Hardware and software layer 1202 includes hardware and software components. Examples of hardware components include: mainframes 1204; RISC (Reduced Instruction Set Computer) architecture based servers 1206; servers 1208; blade servers 1210; storage devices 1212; and networks and networking components 1214. In some embodiments, software components include network application server software 1216 and database software 1218.

Virtualization layer 1220 provides an abstraction layer from which the following examples of virtual entities may be provided: virtual servers 1222; virtual storage 1224; virtual networks 1226, including virtual private networks; virtual applications and operating systems 1228; and virtual clients 1230.

In one example, management layer 1232 may provide the functions described below. Resource provisioning 1234 provides dynamic procurement of computing resources and other resources that are utilized to perform tasks within the cloud computing environment. Metering and Pricing 1236 provide cost tracking as resources are utilized within the cloud computing environment, and billing or invoicing for consumption of these resources. In one example, these resources may include application software licenses. Security provides identity verification for cloud consumers and tasks, as well as protection for data and other resources. User portal 1238 provides access to the cloud computing environment for consumers and system administrators. Service level management 1240 provides cloud computing resource allocation and management such that required service levels are met. Service Level Agreement (SLA) planning and fulfillment 1242 provide pre-arrangement for, and procurement of, cloud computing resources for which a future requirement is anticipated in accordance with an SLA.

Workloads layer 1244 provides examples of functionality for which the cloud computing environment may be utilized. Examples of workloads and functions which may be provided from this layer include: mapping and navigation 1246; software development and lifecycle management 1248; virtual classroom education delivery 1250; data analytics processing 1252; transaction processing 1254; and VQE algorithm processing 1256. Various embodiments of the present invention can utilize the cloud computing environment described with reference to FIGS. 11 and 12 to map VQE algorithms onto one or more quantum processors 308 having a multilevel hierarchical tree architecture, such as an X-tree architecture.

The present invention may be a system, a method, and/or a computer program product at any possible technical detail level of integration. The computer program product may include a computer readable storage medium (or media) having computer readable program instructions thereon for causing a processor to carry out aspects of the present invention. The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present invention may be assembler instructions, instruction-set-architecture (ISA) instructions, machine instructions, machine dependent instructions, microcode, firmware instructions, state-setting data, configuration data for integrated circuitry, or either source code or object code written in any combination of one or more programming languages, including an object oriented programming language such as Smalltalk, C++, or the like, and procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects of the present invention.

Aspects of the present invention are described herein with reference to flowchart illustrations and/or block diagrams of methods, apparatus (systems), and computer program products according to embodiments of the invention. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various embodiments of the present invention. In this regard, each block in the flowchart or block diagrams may represent a module, segment, or portion of instructions, which comprises one or more executable instructions for implementing the specified logical function(s). In some alternative implementations, the functions noted in the blocks may occur out of the order noted in the Figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware based systems that perform the specified functions or acts or carry out combinations of special purpose hardware and computer instructions.

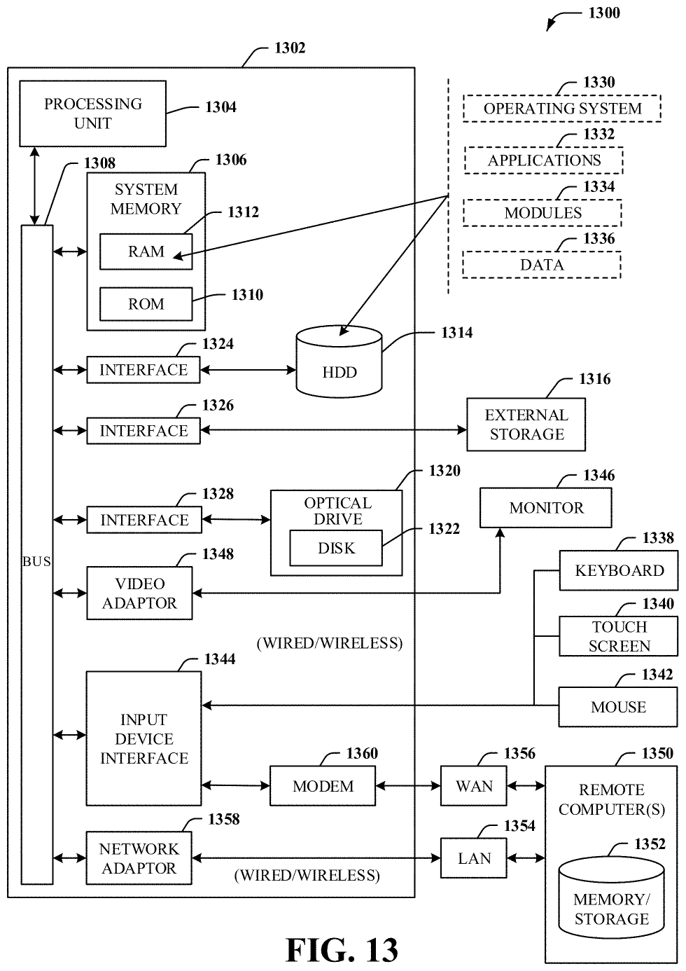

In order to provide additional context for various embodiments described herein, FIG. 13 and the following discussion are intended to provide a general description of a suitable computing environment 1300 in which the various embodiments of the embodiment described herein can be implemented. While the embodiments have been described above in the general context of computer-executable instructions that can run on one or more computers, those skilled in the art will recognize that the embodiments can be also implemented in combination with other program modules and/or as a combination of hardware and software.

Generally, program modules include routines, programs, components, data structures, and/or the like that perform particular tasks or implement particular abstract data types. Moreover, those skilled in the art will appreciate that the inventive methods can be practiced with other computer system configurations, including single-processor or multiprocessor computer systems, minicomputers, mainframe computers, Internet of Things (“IoT”) devices, distributed computing systems, as well as personal computers, hand-held computing devices, microprocessor-based or programmable consumer electronics, and the like, each of which can be operatively coupled to one or more associated devices.

The illustrated embodiments of the embodiments herein can be also practiced in distributed computing environments where certain tasks are performed by remote processing devices that are linked through a communications network. In a distributed computing environment, program modules can be located in both local and remote memory storage devices. For example, in one or more embodiments, computer executable components can be executed from memory that can include or be comprised of one or more distributed memory units. As used herein, the term “memory” and “memory unit” are interchangeable. Further, one or more embodiments described herein can execute code of the computer executable components in a distributed manner, e.g., multiple processors combining or working cooperatively to execute code from one or more distributed memory units. As used herein, the term “memory” can encompass a single memory or memory unit at one location or multiple memories or memory units at one or more locations.

Computing devices typically include a variety of media, which can include computer-readable storage media, machine-readable storage media, and/or communications media, which two terms are used herein differently from one another as follows. Computer-readable storage media or machine-readable storage media can be any available storage media that can be accessed by the computer and includes both volatile and nonvolatile media, removable and non-removable media. By way of example, and not limitation, computer-readable storage media or machine-readable storage media can be implemented in connection with any method or technology for storage of information such as computer-readable or machine-readable instructions, program modules, structured data or unstructured data.

Computer-readable storage media can include, but are not limited to, random access memory (“RAM”), read only memory (“ROM”), electrically erasable programmable read only memory (“EEPROM”), flash memory or other memory technology, compact disk read only memory (“CD-ROM”), digital versatile disk (“DVD”), Blu-ray disc (“BD”) or other optical disk storage, magnetic cassettes, magnetic tape, magnetic disk storage or other magnetic storage devices, solid state drives or other solid state storage devices, or other tangible and/or non-transitory media which can be used to store desired information. In this regard, the terms “tangible” or “non-transitory” herein as applied to storage, memory or computer-readable media, are to be understood to exclude only propagating transitory signals per se as modifiers and do not relinquish rights to all standard storage, memory or computer-readable media that are not only propagating transitory signals per se.

Computer-readable storage media can be accessed by one or more local or remote computing devices, e.g., via access requests, queries or other data retrieval protocols, for a variety of operations with respect to the information stored by the medium.

Communications media typically embody computer-readable instructions, data structures, program modules or other structured or unstructured data in a data signal such as a modulated data signal, e.g., a carrier wave or other transport mechanism, and includes any information delivery or transport media. The term “modulated data signal” or signals refers to a signal that has one or more of its characteristics set or changed in such a manner as to encode information in one or more signals. By way of example, and not limitation, communication media include wired media, such as a wired network or direct-wired connection, and wireless media such as acoustic, RF, infrared and other wireless media.

With reference again to FIG. 13, the example environment 1300 for implementing various embodiments of the aspects described herein includes a computer 1302, the computer 1302 including a processing unit 1304, a system memory 1306 and a system bus 1308. The system bus 1308 couples system components including, but not limited to, the system memory 1306 to the processing unit 1304. The processing unit 1304 can be any of various commercially available processors. Dual microprocessors and other multi-processor architectures can also be employed as the processing unit 1304.

The system bus 1308 can be any of several types of bus structure that can further interconnect to a memory bus (with or without a memory controller), a peripheral bus, and a local bus using any of a variety of commercially available bus architectures. The system memory 1306 includes ROM 1310 and RAM 1312. A basic input/output system (“BIOS”) can be stored in a non-volatile memory such as ROM, erasable programmable read only memory (“EPROM”), EEPROM, which BIOS contains the basic routines that help to transfer information between elements within the computer 1302, such as during startup. The RAM 1312 can also include a high-speed RAM such as static RAM for caching data.

The computer 1302 further includes an internal hard disk drive (“HDD”) 1314 (e.g., EIDE, SATA), one or more external storage devices 1316 (e.g., a magnetic floppy disk drive (“FDD”) 1316, a memory stick or flash drive reader, a memory card reader, and/or the like) and an optical disk drive 1320 (e.g., which can read or write from a CD-ROM disc, a DVD, a BD, and/or the like). While the internal HDD 1314 is illustrated as located within the computer 1302, the internal HDD 1314 can also be configured for external use in a suitable chassis (not shown). Additionally, while not shown in environment 1300, a solid state drive (“SSD”) could be used in addition to, or in place of, an HDD 1314. The HDD 1314, external storage device(s) 1316 and optical disk drive 1320 can be connected to the system bus 1308 by an HDD interface 1324, an external storage interface 1326 and an optical drive interface 1328, respectively. The interface 1324 for external drive implementations can include at least one or both of Universal Serial Bus (“USB”) and Institute of Electrical and Electronics Engineers (“IEEE”) 1394 interface technologies. Other external drive connection technologies are within contemplation of the embodiments described herein.

The drives and their associated computer-readable storage media provide nonvolatile storage of data, data structures, computer-executable instructions, and so forth. For the computer 1302, the drives and storage media accommodate the storage of any data in a suitable digital format. Although the description of computer-readable storage media above refers to respective types of storage devices, it should be appreciated by those skilled in the art that other types of storage media which are readable by a computer, whether presently existing or developed in the future, could also be used in the example operating environment, and further, that any such storage media can contain computer-executable instructions for performing the methods described herein.

A number of program modules can be stored in the drives and RAM 1312, including an operating system 1330, one or more application programs 1332, other program modules 1334 and program data 1336. All or portions of the operating system, applications, modules, and/or data can also be cached in the RAM 1312. The systems and methods described herein can be implemented utilizing various commercially available operating systems or combinations of operating systems.

Computer 1302 can optionally comprise emulation technologies. For example, a hypervisor (not shown) or other intermediary can emulate a hardware environment for operating system 1330, and the emulated hardware can optionally be different from the hardware illustrated in FIG. 13. In such an embodiment, operating system 1330 can comprise one virtual machine (“VM”) of multiple VMs hosted at computer 1302. Furthermore, operating system 1330 can provide runtime environments, such as the Java runtime environment or the .NET framework, for applications 1332. Runtime environments are consistent execution environments that allow applications 1332 to run on any operating system that includes the runtime environment. Similarly, operating system 1330 can support containers, and applications 1332 can be in the form of containers, which are lightweight, standalone, executable packages of software that include, e.g., code, runtime, system tools, system libraries and settings for an application.

Further, computer 1302 can be enable with a security module, such as a trusted processing module (“TPM”). For instance with a TPM, boot components hash next in time boot components, and wait for a match of results to secured values, before loading a next boot component. This process can take place at any layer in the code execution stack of computer 1302, e.g., applied at the application execution level or at the operating system (“OS”) kernel level, thereby enabling security at any level of code execution.

A user can enter commands and information into the computer 1302 through one or more wired/wireless input devices, e.g., a keyboard 1338, a touch screen 1340, and a pointing device, such as a mouse 1342. Other input devices (not shown) can include a microphone, an infrared (“IR”) remote control, a radio frequency (“RF”) remote control, or other remote control, a joystick, a virtual reality controller and/or virtual reality headset, a game pad, a stylus pen, an image input device, e.g., camera(s), a gesture sensor input device, a vision movement sensor input device, an emotion or facial detection device, a biometric input device, e.g., fingerprint or iris scanner, or the like. These and other input devices are often connected to the processing unit 1304 through an input device interface 1344 that can be coupled to the system bus 1308, but can be connected by other interfaces, such as a parallel port, an IEEE 1394 serial port, a game port, a USB port, an IR interface, a BLUETOOTH® interface, and/or the like.

A monitor 1346 or other type of display device can be also connected to the system bus 1308 via an interface, such as a video adapter 1348. In addition to the monitor 1346, a computer typically includes other peripheral output devices (not shown), such as speakers, printers, and/or the like.

The computer 1302 can operate in a networked environment using logical connections via wired and/or wireless communications to one or more remote computers, such as a remote computer(s) 1350. The remote computer(s) 1350 can be a workstation, a server computer, a router, a personal computer, portable computer, microprocessor-based entertainment appliance, a peer device or other common network node, and typically includes many or all of the elements described relative to the computer 1302, although, for purposes of brevity, only a memory/storage device 1352 is illustrated. The logical connections depicted include wired/wireless connectivity to a local area network (“LAN”) 1354 and/or larger networks, e.g., a wide area network (“WAN”) 1356. Such LAN and WAN networking environments are commonplace in offices and companies, and facilitate enterprise-wide computer networks, such as intranets, all of which can connect to a global communications network, e.g., the Internet.

When used in a LAN networking environment, the computer 1302 can be connected to the local network 1354 through a wired and/or wireless communication network interface or adapter 1358. The adapter 1358 can facilitate wired or wireless communication to the LAN 1354, which can also include a wireless access point (“AP”) disposed thereon for communicating with the adapter 1358 in a wireless mode.

When used in a WAN networking environment, the computer 1302 can include a modem 1360 or can be connected to a communications server on the WAN 1356 via other means for establishing communications over the WAN 1356, such as by way of the Internet. The modem 1360, which can be internal or external and a wired or wireless device, can be connected to the system bus 1308 via the input device interface 1344. In a networked environment, program modules depicted relative to the computer 1302 or portions thereof, can be stored in the remote memory/storage device 1352. It will be appreciated that the network connections shown are example and other means of establishing a communications link between the computers can be used.

When used in either a LAN or WAN networking environment, the computer 1302 can access cloud storage systems or other network-based storage systems in addition to, or in place of, external storage devices 1316 as described above. Generally, a connection between the computer 1302 and a cloud storage system can be established over a LAN 1354 or WAN 1356 e.g., by the adapter 1358 or modem 1360, respectively. Upon connecting the computer 1302 to an associated cloud storage system, the external storage interface 1326 can, with the aid of the adapter 1358 and/or modem 1360, manage storage provided by the cloud storage system as it would other types of external storage. For instance, the external storage interface 1326 can be configured to provide access to cloud storage sources as if those sources were physically connected to the computer 1302.

The computer 1302 can be operable to communicate with any wireless devices or entities operatively disposed in wireless communication, e.g., a printer, scanner, desktop and/or portable computer, portable data assistant, communications satellite, any piece of equipment or location associated with a wirelessly detectable tag (e.g., a kiosk, news stand, store shelf, and/or the like), and telephone. This can include Wireless Fidelity (“Wi-Fi”) and BLUETOOTH® wireless technologies. Thus, the communication can be a predefined structure as with a conventional network or simply an ad hoc communication between at least two devices.

What has been described above include mere examples of systems, computer program products and computer-implemented methods. It is, of course, not possible to describe every conceivable combination of components, products and/or computer-implemented methods for purposes of describing this disclosure, but one of ordinary skill in the art can recognize that many further combinations and permutations of this disclosure are possible. Furthermore, to the extent that the terms “includes,” “has,” “possesses,” and the like are used in the detailed description, claims, appendices and drawings such terms are intended to be inclusive in a manner similar to the term “comprising” as “comprising” is interpreted when employed as a transitional word in a claim. The descriptions of the various embodiments have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. An apparatus, comprising:
a superconducting quantum processor topology that employs an X-tree architecture to delineate connections between superconducting qubits, wherein a total number of the connections is less than a total number of the superconducting qubits.

2. The apparatus of claim 1, wherein the superconducting qubits are represented in the X-tree architecture as at least one member selected from the group consisting of a root node and a leaf node.

3. The apparatus of claim 2, wherein the X-tree architecture is segmented into a plurality of levels, and wherein a connection between the root node and the leaf node crosses between two levels from the plurality of levels.

4. The apparatus of claim 2, wherein the superconducting quantum processor topology comprises five superconducting qubits, wherein a first superconducting qubit from the five superconducting qubits is represented as the root node in a first level of the X-tree architecture, and wherein four other superconducting qubits from the five superconducting qubits are represented as leaf nodes in a second level of the X-tree architecture.

5. A system, comprising:
a memory that stores computer executable components; and
a processor, operably coupled to the memory, and that executes the computer executable components stored in the memory, wherein the computer executable components comprise:
a compiler component that maps a variational quantum eigensolver algorithm to a superconducting quantum processor that includes qubit connectivity characterized by a multilevel hierarchical tree architecture.

6. The system of claim 5, further comprising:
a layout component that generates an initial hierarchical layout that maps physical qubits of the superconducting quantum processor with logical qubits included in a plurality of Pauli strings employed by the variational quantum eigensolver algorithm.

7. The system of claim 6, wherein the multilevel hierarchical tree architecture includes a root node connected to a leaf node across different levels, wherein the root node is connected to multiple leaf nodes.

8. The system of claim 6, wherein the multilevel hierarchical tree is an X-tree architecture.

9. The system of claim 6, wherein the variational quantum eigensolver algorithm defines quantum computations executable by the superconducting quantum processor, and wherein the system further comprising:
a mapping component that determines how many of the quantum computations employ a first logical qubit from the logical qubits, and how many of the quantum computations employ a second logical qubit from the logical qubits.

10. The system of claim 9, wherein the first logical qubit is mapped to a more central level of the multilevel hierarchical tree architecture than the second logical qubit in the initial hierarchical layout based on the first logical qubit being employed in more of the quantum computations than the second logical qubit.

11. The system of claim 10, further comprising:
a synthesis component that synthesizes a quantum circuit that expresses a Pauli string from the plurality of Pauli strings through a series of qubit connection selections, wherein the synthesis component selects a qubit connection between the logical qubits based on an effect of a previously selected qubit connection on a mapping of the physical qubits with the logical qubits; and
a routing component that alters a position of a logical qubit on the multilevel hierarchical tree architecture based on the qubit connection.

12. The system of claim 11, wherein synthesizing the quantum circuit and altering the position of the logical qubit are performed in conjunction with each other.

13. A computer-implemented method, comprising:
mapping, by a system operatively coupled to a processor, a variational quantum eigensolver algorithm to a superconducting quantum processor that includes qubit connectivity characterized by a multilevel hierarchical tree architecture.

14. The computer-implemented method of claim 13, further comprising:
generating, by the system, an initial hierarchical layout that maps physical qubits of the superconducting quantum processor with logical qubits included in a plurality of Pauli strings employed by the variational quantum eigensolver algorithm.

15. The computer-implemented method of claim 14, wherein the multilevel hierarchical tree architecture includes a root node connected to a leaf node across different levels, wherein the root node is connected to multiple leaf nodes.

16. The computer-implemented method of claim 14, wherein the multilevel hierarchical tree is an X-tree architecture.

17. The computer-implemented method of claim 14, wherein the variational quantum eigensolver algorithm defines quantum computations executable by the superconducting quantum processor, and wherein the system further comprising:
determining, by the system, how many of the quantum computations employ a first logical qubit from the logical qubits, and how many of the quantum computations employ a second logical qubit from the logical qubits.

18. The computer-implemented method of claim 17, wherein the first logical qubit is mapped to a more central level of the multilevel hierarchical tree architecture than the second logical qubit in the initial hierarchical layout based on the first logical qubit being employed in more of the quantum computations than the second logical qubit.

19. The computer-implemented method of claim 18, further comprising:
synthesizing, by the system, a quantum circuit that expresses a Pauli string from the plurality of Pauli strings through a series of qubit connection selections, wherein a selection from the series of qubit connection selections is based on an effect of a previously selected qubit connection on the mapping of the physical qubits with the logical qubits; and
altering, by the system, a position of a logical qubit on the multilevel hierarchical tree architecture based on the selection.

20. The computer-implemented method of claim 19, wherein the synthesizing the quantum circuit and executing the altering the position of the logical qubit are performed in conjunction with each other.
